(19) United States
(12) Patent Application Publication
(10) Pub. No.: US 2008/0157221 A1
(43) Pub. Date: Jul. 3, 2008

(54) STRUCTURE OF SEMICONDUCTOR DEVICE FOR DECREASING CHIP AREA AND MANUFACTURING METHOD THEREOF

(76) Inventor: Yong-Geun Lee, Chungcheongbuk-do (KR)

Correspondence Address: SHERR & NOURSE, PLLC, 620 HERNDON PARKWAY, SUITE 200, HERNDON, VA, 20170, US

(21) Appl. No.: 11/957,955

(22) Filed: Dec. 17, 2007

(30) Foreign Application Priority Data
Dec. 27, 2006 (KR) 10-2006-0135521

(51) Int. Cl. H01L 27/11; H01L 21/8244

(52) U.S. Cl. 257/390; 438/128; 257/E27.098; 257/E21.661

(57) ABSTRACT

A method of manufacturing a semiconductor device for decreasing a chip area by changing a connecting structure of pull up transistors and pull down transistors are disclosed. The semiconductor device can include pull up and pull down transistors including a first pull down transistor, a first pull up transistor, a second pull up transistor and a second pull down transistor, the first pull down transistor, the first pull up transistor, the second pull up transistor and the second pull down transistor being sequentially arranged in a series form on a SRAM, and line type contacts and metal lines formed on the respective pull up and pull down transistors. The line type contacts formed on the first pull down transistor and the first pull up transistor are connected to each other by the metal lines to connect an inverter that includes the first pull down transistor and the first pull up transistor to an opposite inverter, and the line type contacts formed on the second pull up transistor and the second pull down transistor are connected to each other by the metal lines to connect an inverter that includes the second pull up transistor and the second pull down transistor to an opposite inverter.

The present application claims priority under 35 U.S.C. 119 to Korean Patent Application No. 10-2006-0135521 (filed on Dec. 27, 2006), which is hereby incorporated by reference in its entirety.

### BACKGROUND

Aspects of semiconductor technology have focused on reducing a chip area of a logic device. For instance, attempts have been made for changing a form of a pad of a semiconductor device or decreasing a library logic region. Another method involves decreasing an area of a static random access memory (SRAM) which is essentially included in various semiconductor devices as well as a logic device.

The SRAM is a type of semiconductor memory, particularly a random access memory having a flip-flop type memory cell. Because it retains its contents as long as power remains applied and does not require a complicated refresh clock, the SRAM may be applicable in a small capacity memory or a cache memory.

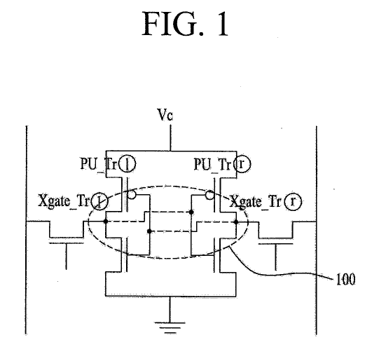

As illustrated in example FIG. 1, an SRAM cell having a connecting structure of pull-up transistors and pull-down transistors. A logical operation may be performed in two pull-down NMOS transistor logic blocks, and a pull-up operation is performed in a pull-up latch which includes two PMOS transistors arranged in a cross-coupled form. Region 100 illustrates a connecting structure of the pull-up transistors and the pull-down transistors.

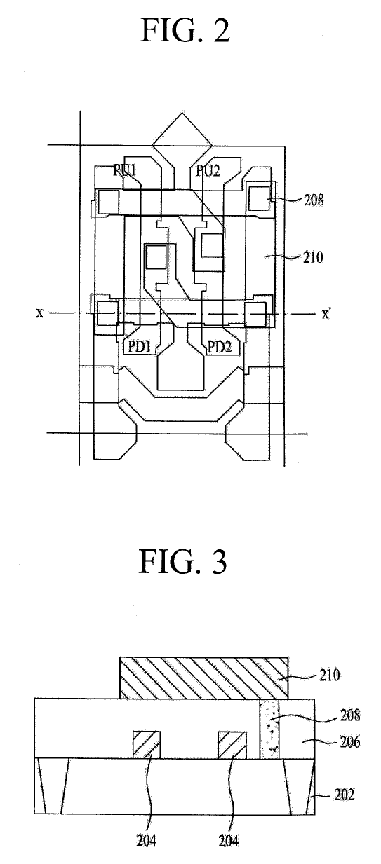

As illustrated in example FIG. 2, a wiring connecting structure of an SRAM cell in region 100. The pull-up transistors and the pull-down transistors may be arranged parallel such that the first pull-up transistor and the second pull-up transistor may be disposed at an upper portion and the first pull-down transistor and the second pull-down transistor may be disposed at a lower portion. Contacts 208 may be connected to metal lines 210 arranged spatially apart from each other by a gap to maintain a pitch of metal lines 210.

As illustrated in example FIG. 3, an SRAM cell taken along line X-X′ of example FIG. 2 may include forming active layer 202 in a semiconductor substrate. Gate electrodes 204 may then be formed on and/or over partial regions of active layer 202. Gate insulating film 206 may then be formed on and/or over active layer 202 including gate electrodes 204. A contact hole may then be formed by etching gate insulating film 206 to expose a portion of the uppermost surface of active layer 202. Contact plug 208 may then be formed by filling an electrically conductive material in the contact hole. Metal line 210 may then be formed on and/or over a partial region of gate insulating film 206 and connected to contact plug 208.

The pull-up transistors and the pull-down transistors illustrated in example FIG. 2 are arranged parallel such that the first pull-up transistor and the second pull-up transistor may be disposed at an upper portion and the first pull-down transistor and the second pull-down transistor may be disposed at a lower portion. In order to connect an inverter formed by the first pull-up and first pull-down transistors to an opposite inverter and connect an inverter formed by the second pull-up and second pull-down transistors to an opposite inverter, metal lines 210 may be used. This may result in an arrangement of metal lines 210 spaced apart from each other with a regular gap to maintain a pitch of the metal lines 210.

However, because such an SRAM has such wiring connecting structure as illustrated in example FIG. 2, the overall area of the SRAM may be increased in order to provide a plurality of integrated transistors while maintaining a pitch of the metal lines.

### SUMMARY

Embodiments relate to a semiconductor device having a reduced chip area and a manufacturing method thereof that is adequate for reducing an area of an SRAM by changing a connecting structure of pull-up transistors and pull-down transistors, which decisively influence an area of a SRAM cell.

Embodiments relate to a semiconductor device having a reduced chip area and a reduced area of a SRAM cell by changing a connecting manner of pull-up and pull-down transistors in the SRAM cell embedded in a logic device in order to reduce the chip area.

Embodiments relate to a semiconductor device having a reduced chip area and a manufacturing method thereof that changes the arrangement of transistors in a SRAM cell from a parallel form to a series form and substitutes a metal line with a line-type contact.

Embodiments relate to a semiconductor device that can include at least one of the following: a first pull down transistor, a first pull up transistor, a second pull up transistor and a second pull down transistor sequentially arranged in series over an SRAM; and a plurality of line-type contacts and metal lines formed over a respective pull-up and pull-down transistor. In accordance with embodiments, the line-type contacts formed over the first pull-down transistor and the first pull-up transistor are connected to each other by the metal lines to connect an inverter formed by the first pull down transistor and the first pull up transistor to an opposite inverter, and the line-type contacts formed over the second pull-up transistor and the second pull-down transistor are connected to each other by the metal lines to connect an inverter formed by the second pull-up transistor and the second pull-down transistor to an opposite inverter.

Embodiments relate to a semiconductor device that can include at least one of the following: sequentially forming a first pull down transistor, a first pull up transistor, a second pull up transistor, and a second pull down transistor in series from an upper portion over a SRAM; and forming line type contacts and metal lines over the respective pull up transistors and pull down transistors. In accordance with embodiments, forming the line-type contacts and metal lines includes connecting the line-type contacts formed over the first pull down transistor and the first pull up transistor to each other by the metal lines, and connecting the line-type contacts formed over the second pull up transistor and the second pull down transistor to each other by the metal lines.

Embodiments relate to a method for manufacturing a semiconductor device that can include at least one of the following steps: forming an active layer including isolation layers in a semiconductor substrate; forming at least one gate electrode over the active layer; exposing a partial uppermost surface of the active layer; forming an insulating film over the active layer including the at least one gate electrode; forming at least one contact hole in the insulating film exposing the uppermost surface of one of the at least one gate electrode; forming a contact plug in the at least one contact hole; and then forming a short metal line over the uppermost surface of the contact plug.

### DRAWINGS

Example FIGS. 1 to 3 illustrate a circuit diagram and a wiring connecting structure of an SRAM cell.

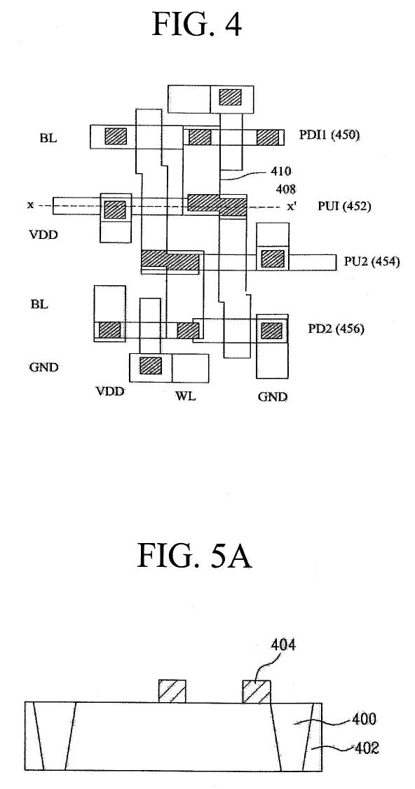

Example FIG. 4 illustrates a view of a wiring connecting structure of an SRAM cell, in accordance with embodiments.

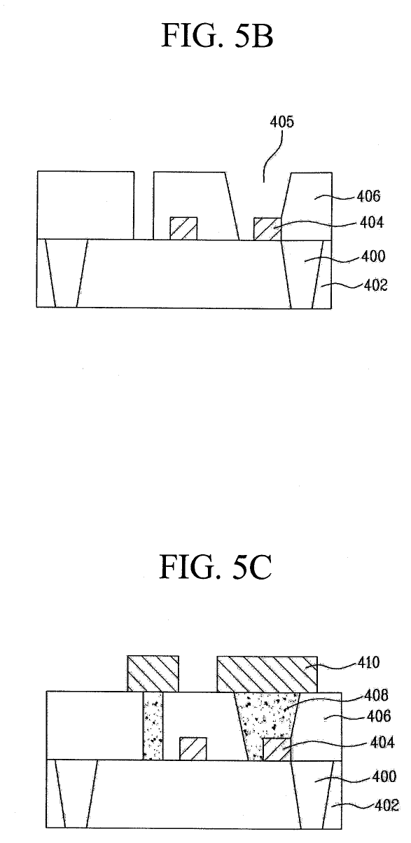

Example FIGS. 5A to 5C illustrate a method for manufacturing an SRAM cell, in accordance with embodiments.

### DESCRIPTION

As illustrated in example FIG. 4, a wiring connecting structure of a SRAM cell for decreasing a chip area can include first pull-down transistor 450, first pull-up transistor 452, second pull-up transistor 454, and a second pull-down transistor 456 sequentially arranged in series from an upper portion to a lower portion. In order to connect an inverter (which can include first pull-down transistor 450 and first pull-up transistor 452) to an opposite inverter and connect an inverter (which can include second pull-up transistor 454 and second pull-down transistor 456) to an opposite inverter, line-type contacts 408 can be formed, instead of connecting the inverters only by metal lines.

A wiring pattern can be formed such that the overall contact plugs of line-type contacts 408 can be covered by short metal lines 410, thereby reducing the size of the SRAM cell.

Although embodiments illustrate first pull down transistor 450, first pull up transistor 452, second pull up transistor 454, and second pull down transistor 456 sequentially arranged, the arrangement order of the transistors can be changed variously according to design requirements, under the condition of arranging the transistors in a series form.

As illustrated in example FIG. 5A, a method for manufacturing the SRAM cell can include forming active layer 402 including isolation layers 400 for dividing the SRAM cell in a semiconductor substrate. A pair of gate electrodes 404 can then be formed on and/or over active layer 402. Gate electrodes 402 can then be etched through a dry etching or a wet etching using a mask pattern formed by exposure and development to expose a partial surface of active layer 402. The mask pattern can then be removed.

As illustrated in example FIG. 5B, insulating film 406 can then be deposited on and/or over active layer 402 including gate electrodes 404. Insulating film 406 can then be selectively etched to thereby form contact hole 405 exposing a portion of the uppermost surface of one gate electrode 404.

As illustrated in example FIG. 5C, an electrically conductive material can then be filled in contact hole 405 to form contact plug 408. Contact plug 408 can then be planarized by a chemical mechanical polishing (CMP) process. Short metal line 410 can then be formed to cover the whole uppermost surface of contact plug 408.

As described above, the arrangement of the pull up and pull down transistors, which decisively influence the area of the SRAM cell, can be changed from a parallel form to a series form. The transistors can also be connected through a line-type contact instead of a metal line, thereby reducing the cell size.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An apparatus comprising:
a first pull down transistor, a first pull up transistor, a second pull up transistor and a second pull down transistor sequentially arranged in series over an SRAM; and
a plurality of line-type contacts and metal lines formed over a respective pull-up and pull-down transistor,
wherein the line-type contacts formed over the first pull-down transistor and the first pull-up transistor are connected to each other by the metal lines to connect an inverter formed by the first pull down transistor and the first pull up transistor to an opposite inverter, and the line-type contacts formed over the second pull-up transistor and the second pull-down transistor are connected to each other by the metal lines to connect an inverter formed by the second pull-up transistor and the second pull-down transistor to an opposite inverter.

2. The apparatus of claim 1, wherein each of the pull-up and the pull-down transistors includes a gate electrode formed over a partial region of an active layer, an insulating film formed over the active layer including the gate electrode, and a contact plug extending through a contact hole and connected to a part of the gate electrode.

3. The apparatus of claim 2, wherein the metal lines are formed over and cover the entire uppermost surface of the contact plug.

4. A method comprising:
sequentially forming a first pull down transistor, a first pull up transistor, a second pull up transistor, and a second pull down transistor in series from an upper portion over a SRAM; and
forming line type contacts and metal lines over the respective pull up transistors and pull down transistors,
wherein forming the line-type contacts and metal lines includes connecting the line-type contacts formed over the first pull down transistor and the first pull up transistor to each other by the metal lines, and connecting the line-type contacts formed over the second pull up transistor and the second pull down transistor to each other by the metal lines.

5. The method of claim 4, wherein the line-type contacts connect an inverter that includes the first pull down transistor and the first pull up transistor to an opposite inverter, and also connect an inverter that includes the second pull up transistor and the second pull down transistor to an opposite inverter.

6. The method of claim 4, wherein sequentially forming a first pull down transistor, a first pull up transistor, a second pull up transistor, and a second pull down transistor each comprises:
forming a gate electrode over an active layer of a substrate;
forming an insulating film over the active layer including the gate electrode;
forming a contact hole in the insulating film; and then forming a contact plug in the contact hole for connection to at least a portion of the gate electrode.

7. The method of claim 6, wherein forming the contact hole comprises etching the insulating film to expose at least a portion of the uppermost surface of the gate electrode.

8. The method of claim 6, wherein forming the contact plug comprises:
filling the contact hole with an electrically conductive material; and then
planarizing the electrically conductive material.

9. The method according to claim 8, wherein the metal line is formed over the entire uppermost surface of the contact plug.

10. The method of claim 6, wherein the contact hole is formed through an etching process.

11. A method comprising:
forming an active layer including isolation layers in a semiconductor substrate;
forming at least one gate electrode over the active layer;
exposing a partial uppermost surface of the active layer;
forming an insulating film over the active layer including the at least one gate electrode;
forming at least one contact hole in the insulating film exposing the uppermost surface of one of the at least one gate electrode;
forming a contact plug in the at least one contact hole; and then
forming a short metal line over the uppermost surface of the contact plug.

12. The method of claim 11, wherein exposing the partial uppermost surface of the active layer comprises:
etching the at least one gate electrode through a dry etching using a mask pattern formed by exposure and development; and then
removing the mask pattern.

13. The method of claim 11, wherein exposing the partial uppermost surface of the active layer comprises:
etching the at least one gate electrode through a wet etching using a mask pattern formed by exposure and development; and then
removing the mask pattern.

14. The method of claim 11, wherein forming the at least one contact hole includes etching the insulating film.

15. The method of claim 11, wherein forming the contact plug comprises:
filling the contact hole with an electrically conductive material; and then
planarizing the electrically conductive material.

16. The method of claim 15, wherein the electrically conductive material is planarized through a chemical mechanical polishing process.

17. The method of claim 11, wherein the short metal line is formed to cover the entire uppermost surface of the contact plug.

18. The method of claim 11, wherein forming at least one contact hole in the insulating film comprises forming a pair of contact holes exposing the uppermost surface of one of the at least one gate electrode and exposing the uppermost surface of the semiconductor substrate.

19. The method of claim 18, wherein forming the contact hole comprises:
filling each of the contact holes with an electrically conductive material; and then
planarizing the electrically conductive material.

20. The method of claim 19, wherein the short metal line is formed to cover the entire uppermost surface of the contact plugs.
